(19) United States
(12) Patent Application Publication
(10) Pub. No.: US 2007/0082432 A1
(43) Pub. Date: Apr. 12, 2007

(54) Variable exposure photolithography

(76) Inventor: Wai Mun Lee, Fremont, CA (US)

Correspondence Address: MORGAN LEWIS & BOCKIUS LLP, 1111 PENNSYLVANIA AVENUE NW, WASHINGTON, DC, 20004, US

(21) Appl. No.: 11/515,798

(22) Filed: Sep. 6, 2006

Related U.S. Application Data
(60) Provisional application No. 60/713,733, filed on Sep. 6, 2005.

(51) Int. Cl. H01L 21/84; H01L 21/00

(52) U.S. Cl. 438/149

(57) ABSTRACT

A method of forming a thin film transistor on a substrate including an insulating layer and layers of etchable material over the insulating layer by depositing a layer of photoresist made of polymers that are altered by actinic energy. In the method, an amine cross-linking agent is used with portions of the photoresist. The photoresist is differentially exposed to actinic energy to convert portions of the photoresist and portions are removed. Etching is selectively performed, followed by development of the remaining photoresist, followed by additional etching.

### CROSS REFERENCE TO RELATED APPLICATION

This application claims the benefit of U.S. Provisional Application No. 60/713,733, filed Sep. 6, 2005, assigned to the assignee of this application and incorporated by reference herein.

### FIELD OF THE INVENTION

This invention relates to a method of performing a photolithographic manufacturing process useful in a variety of products such as semiconductors and liquid crystal displays, wherein a single layer of photoresist can be used to form two or more resist patterns. More particularly, the invention relates to a method for fabricating a thin-film-transistor using a process in which in one step there is used one layer of photoresist, and with differential exposure to light from sequential exposures to light using a single mask or a plurality of masks, or from differential exposure to light using one or more masks followed by blanket exposure, to form multiple patterns on a substrate.

### BACKGROUND OF THE INVENTION

Photolithographic processes have been used extensively in the manufacturing of integrated circuits (IC), memory, and liquid crystal display (LCD) devices. Photolithography refers to a series of processes in which desired patterns are formed by transcribing a pattern drawn on a mask to a substrate on which a thin film is deposited, and includes a plurality of processes, such as photoresist application, exposure, development, or the like.

A liquid crystal display device includes a color filter substrate, which is a first substrate, an array substrate, which is a second substrate, and a liquid crystal material formed between the two substrates. A thin film transistor, which uses amorphous silicon or polycrystalline silicon as a channel layer, is used as a switching device of the liquid crystal display device. A process for fabricating the liquid crystal display device usually requires a plurality of photo-mask processes in fabricating the array substrate including the thin film transistor.

Samsung developed a process whereby at least two patterns could be formed through one photolithography process. This process, plus excellent background material on the fabrication steps for a liquid crystal display, are described in U.S. Pat. No. 6,887,742, the disclosure of which is incorporated here by reference thereto for all legal purposes. An exemplary thin-film-transistor (TFT) such as can be fabricated using methods described herein is shown in FIG. 1 showing a plan-view and FIG. 2 showing cross-sectional details (along line II-II in FIG. 1) of major structures depicted in FIG. 1 (same FIGS. 1 and 2 in U.S. Pat. No. 6,887,742). In the drawings, the thickness of layers and distances are exaggerated for clarity.

In order to prevent the delay or distortion of signals applied to wires, materials having a low resistivity, such as copper, aluminum, or aluminum alloy, are generally used. However, because of the poor contact properties between aluminum or aluminum alloy and indium tin oxide (ITO), which is often used as a transparent electrode in a pad portion of a liquid crystal display, a different material having good contact properties such as chromium and molybdenum is used to connect aluminum with ITO. In FIGS. 1 and 2 showing a plan view and a detailed cross-sectional view of a TFT array, gate wires including a lower layer of conductive material having good contact properties with indium tin oxide, such as molybdenum or molybdenum alloy, and chromium, and an upper layer of conductive material having a low resistivity, such as aluminum (Al) or aluminum alloy (Al alloy), are formed on an insulating substrate 10. A gate wire includes a gate line (or scanning signal line) 22 extending in the horizontal direction in FIG. 1, a gate pad 24 that is connected to an end of a gate line 22 and transmits a scanning signal from an external circuit to the gate line 22, and a gate electrode 26 that is a part of a thin film transistor. A gate insulating layer 30 of silicon-nitride (SiNx) is formed on and covers the gate wire parts 22, 24, and 26. In FIG. 3a and 3c, it is shown that the gate insulating layer can be formed of SiON with for example an overlaying layer of SiN. The gate insulating layer 30 has a contact hole 74 exposing the gate pad 24 along with a passivation layer 70, which will be formed later, and covers the upper layer 202 of the gate wires 22 and 26. A semiconductor layer 40 such as hydrogenated amorphous silicon is formed in an island-like shape on the gate insulating layer 30 of the gate electrode 26. Ohmic contact layers 55 and 56 (made of such materials as silicide or hydrogenated amorphous silicon heavily doped with impurities like phosphorus) are formed on the semiconductor layer 40. A data wire made of conductive materials such as Mo or Mo alloy and Cr is formed on the ohmic contact layer patterns 55 and 56 and the gate insulating layer 30. The data wire has a data line 62 extending in the vertical direction in FIG. 1 and defining a pixel along with the gate line 22, a data pad 68 that is connected to an end of data line 62 and transmits image signals from an external circuit to the data line 62, a source electrode 65 of a thin film transistor that is connected to the data line 62 and is extended on the ohmic contact layer 55, and a drain electrode 66 of the thin film transistor that is formed on the ohmic contact layer 56 opposite the source electrode 65 with respect to the gate electrode 26 and is separated from the source electrode 65. A passivation layer 70 is formed on the data wire parts 62, 65, 66, and 68, and the semiconductor layer 40 which is not covered by the data wire parts 62, 65, 66, and 68. The passivation layer 70 has contact holes 76 and 78 respectively exposing the drain electrode 66 and the data pad 68, and also has (along with the gate insulating layer 30) another contact hole 74 exposing the lower layer 201 of the gate pad 24. The passivation layer 70 can be made of an insulating material such as SiNx, acrylic organic material, other transparent photo-definable material, or other organic material. The pixel electrode 82, which receives an image signal and generates an electric field with a common electrode of an upper panel, is formed on the passivation layer 70 of the pixel. The pixel electrode 82 is electrically connected to the drain electrode 66 through the contact hole 76, and receives the image signal from the drain electrode 66. A redundant gate pad 84 and a redundant data pad 88, respectively connected to the lower layer 201 of the gate pad 24 and to the data pad 68 through the contact holes 74 and 78, are formed on the passivation layer 70. The pixel electrode 82 overlaps the gate lines 22 or the data lines 62 to make a storage capacitor. If this configuration does not generate enough storage capacitance, a storage wire may be formed with the same layer as the gate wire parts 22, 24, and 26.

FIGS. 3a to 3f shows a detailed cross-sectional view of major components of another exemplary TFT as they exist at the end of certain manufacturing processes employing a mask. FIG. 3b shows details of placing the Gate Lines (GL), which may involve for example Mo/AlNd sputtering leading to deposition of a layer Mo and AlNd (an alloy). A first mask is used to create the pattern, and the photoresist may be removed by dry etch using for example O₂, SF₆, BCl₃, or Cl₂ or an aluminum wet etch formulation. FIG. 3c shows details of fabricating an I stop, including deposition of SiN and SiON to form a gate insulating layer 30, followed by a layer of conductive hydrogenated alpha-silicon and an additional layer of SiN over the TFT, where a mask and wet etching using for example DHF and HF is used to pattern the top layer of SiN. FIG. 3d shows deposition of a pattern of conductive Mo/AlNd electrodes (source electrode 65, drain electrode 66, and a conductive layer at a crossover point) deposited for example by sputtering, masked, and etched with an aqueous nitric acid/acetic acid/and/or phosphoric acid. Then, using the same mask, alpha-Si can be removed by for example plasma etching, and finally the resist and residue is stripped from the surface to leave the structure shown in FIG. 3d. Than, another insulating layer 70 is deposited, followed by forming a photoresist mask and dry etching or wet etching throughholes. This mask is removed, giving the structure shown in FIG. 3e. Then, a layer of ITO is deposited to form the pixel electrode 82, a resist pattern is formed, and ITO is removed by for example aqueous oxalic acid, followed by stripping the resist to give the structure shown in FIG. 3f.

The fabricating process in U.S. Pat. No. 6,887,742 includes a step where two patterns are formed through one photolithography process. FIGS. 4a to 4f are useful to illustrate the process described in this patent. This process required that a photoresist pattern have a first portion, a second portion and a third portion having different thickness on various positions of an etch mask. Generally, the first portion can be described as having a thick layer of photoresist, the second layer can be described as having a layer of photoresist of intermediate thickness, and the third portion can be described as having either a very thin layer or no layer of photoresist. The intermediate thickness layer is achieved by having a single mask having areas of intermediate transmittance, that is, by having the mask have a slit pattern or a grid pattern to control the amount of transmitted light, where the widths and the intervals of the slit and the lattice are smaller than the resolution of the exposure device. See FIG. 4a which depicts at the top a perpendicular view of a circular mash having opaque areas that are black, partial (“50”) light transmittance areas depicted by a grey tone, and full (“100%”) transmittance areas that appear white. The patent mentions another option where this area of intermittent transmittance is a “transmittance control film” or a “partly-transparent layer,” where the mask including a plurality of thin films having a different transmittance value, or a thin film having different thickness depending on positions may be used to control the amount of transmitted light. When used the mask is parallel to the substrate, as depicted by the horizontal line-like structure in the center of FIG. 4a. The substrate has first and second metal layers (M1 and M2, respectively), followed by a layer of photoresist PR. Light passes through the mask and impinges on the photoresist. When the photoresist layer is exposed to light (that is, to converting actinic energy), the polymers of the photoresist layer are disintegrated by the light, and the exposing step is finished when the portion of polymers that is directly exposed to the light are completely disintegrated. At this time, the polymers of a photoresist layer which are exposed through slit patterns or a partly-transparent layer are not completely disintegrated because the amount of incident light is less than that of the directly exposed portion. Finally, the polymers of the photoresist layer hidden by the opaque portions of the mask are not disintegrated. This is depicted in FIG. 4b, where unexposed photoresist is light grey, partially exposed photoresist is depicted as being very dark grey, and fully exposed photoresist is chosen to be an intermediate grey. The exposed film is then developed with we assume to be a basic developer (the resist and developers are not described in the patent), for example tetra-methyl ammonium hydroxide (TMAH) so that the non-disintegrated part of the photoresist pattern is left after developing the photoresist layer. If performed ideally, thinner portion of the photoresist pattern is left at the part that was exposed to less light than the parts that received full exposure, as is shown in FIG. 4c. The thickness of the thick photoresist layer is greater than 1.9 μm, and the thickness of the intermediate thickness portion is equal to or less than half of the thickness of the thickest layer of photoresist.

Such a process as described in U.S. Pat. No. 6,887,742 has a number of difficulties. First, there can be reaction with and contraction of the photoresist/resist residue during multiple etching steps which typically involve plasma etching of both the exposed first and second thin films (M1 and M2). The degree of contraction can depend on the thickness of the resist, as described in FIG. 4d. Then, when the partially developed photoresist is removed by plasma etching to give the structure shown in FIG. 4e, there is significant contraction or movement of the remaining photoresist, and good pattern resolution can not be easily obtained during the subsequent etch of the M2 layer to give the structure shown in FIG. 4f and removal of resist as shown in FIG. 4g. Also, during development the solvent can attack the partially exposed residue not only from the top but also from the sides exposed by removal of exposed resist. Even with this care, it is very difficult to obtain sharp differentiation between areas having no photoresist and areas having an intermediate thickness of photoresist, in part because of the susceptibility of resist beneath the partially exposed resist to have some susceptibility to removal by prolonged exposure to developer and also because there is not a linear transition of resist exposed to light because the occasional photons that penetrates an unusual depth though unexposed resist before reacting with and converting a resist molecule. To view this second problem simplistically, the patent suggests that if a 2 micron thick layer of photoresist is exposed to 50% of the actinic energy required for full conversion, then the top one micron of material nearest the source of actinic energy would be fully converted while the bottom one micron of material would be substantially non-converted. In practice, a layer of photoresist 2 microns thick that has been exposed to 50% of the actinic energy required for full conversion may have two thirds of the resist in the top one micron be converted, while one third of the material in the bottom one micron may be converted. The top portion is not as readily removed by a developer as is fully converted photoresist, while the bottom portion is more removal by the developer than is substantially non-converted photoresist, and this also adversely impacts pattern resolution. Additionally, of course, the differentiation of layer thickness depends on only a portion of the film thickness, in certain areas, being partially converted by the light. Therefore, not only must the amount of light exposure be carefully monitored, but additionally the thickness of the photoresist film must be carefully monitored. Finally, such slit-moderated masks or grid-moderated masks are difficult to manufacture.

Kum-Mi Oh has also described, in U.S. Published Application 2005/0139836, the disclosure of which is incorporated herein for all legal purposes, a process whereby in order to decrease the number of photolithographic processes (photo mask) in TFT patterning for LCD manufacturing, LCD makers are using the “slit exposure” technology which leaves 50% PR area (with conventional exposure only 100% and 0% PR remaining possible). Afterwards, these residues are etched by two step etching processes—first remove the 50% remaining area followed by the second etching process. The process described in this published application faces the same problems described in relation to U.S. Pat. No. 6,887,742. After the first etching process, the remaining PR residue pattern (used to be 100% PR residue area) is contracted due to eating by etchant, which cause problems in pattern resolution. The current split exposure process requires second pattern imaging after transfer of the first pattern to metal film using wet etching solution. After the first etching process, the remaining PR residue pattern (used to be 100% PR residue area) is contracted due to degradation by etching processes, which cause problems in pattern resolution.

### SUMMARY OF THE INVENTION

The current slit exposure process requires second pattern imaging after transfer of the first pattern to metal film using wet etching solution. After the first etching process, the remaining PR residue pattern (which used to be 100% PR residue area) is contracted due to eating by etching processes, which cause problems in pattern resolution. Additionally, there is an indistinct pattern resolution caused by developing resist disposed below exposed resist to be exposed to significant incident light penetrating the above-exposed resist, and to therefore be susceptible to removal by the developer. The present invention addresses these issues. These problems are solved by the invention described herein.

As used herein, the terms “substantially” means to a degree normal in the industry, so that “substantially fully converted” means converted for example by actinic energy to a degree normally encountered in the industry, “substantially non-converted” means that though there may be some conversion caused by incidental light, the material does not undergo a degree of conversion sufficient to negate the difference between converted and unconverted photoresist. By removing “substantially all” of a material, we mean removing a sufficient amount of a material such that the fabrication of the thin film transistor can proceed without generating a commercially unacceptable number of defects. By “substantially not removing” we mean the material in question still exists as a layer of sufficient thickness and integrity to perform its intended function, e.g., as an insulator, as a conductor, as a resist pattern, and so forth. For ease in understanding, unless otherwise stated, the terms “removing” and “not removing” are intended to have the word substantially implicit therein, and also, unless otherwise stated, the terms “converted” and “non-converted” are intended to have the word substantially implicit therein, so that the phrase “removing the converted photoresist” should be interpreted to read “substantially removing the substantially converted photoresist.”

In a broad sense, the invention is a photolithography process for fabricating a thin film transistor comprising:
A) providing a substrate comprising an insulating layer, a first layer of first etchable material disposed over the insulating layer, and a second layer of second etchable material, different from the first etchable material, disposed over the first layer of etchable material;
B) depositing a layer of photoresist on said second layer of etchable material, said layer having an area and a thickness, and said photoresist comprising polymers that are altered by actinic energy and also comprising an amine cross-linking agent that is activated by holding the resist at an elevated curing temperature for a predetermined amount of time;
C) differentially exposing an area of the layer of photoresist to first converting actinic energy, such that there is at least one portion of the area that comprises substantially fully converted photoresist, and at least one portion of the area that comprises substantially non-converted photoresist;
D) in a first developing step developing the layer to remove the substantially fully converted photoresist without removing substantially non-converted resist, or alternatively developing the layer to remove the non-converted resist without removing substantially fully converted photoresist;
E) differentially exposing an area of the layer of photoresist to second converting actinic energy, such that there is at least one portion of the area that comprises converted photoresist, and at least one portion of the area that comprises non-converted photoresist;
F) curing the photoresist at a temperature sufficient to activate the amine cross-linking agent, for example at a temperature between 110° C. to 250° C., typically between 130° C. to 220° C., and preferably (depending on the cross-liking agent selected) between about 150° C. to 200° C.;
G) performing a first etch of the first and second layers of etchable material disposed in areas where the photoresist had been removed;
H) developing the remaining photoresist that had been thermally cured in a second developing step to remove the substantially fully converted photoresist without removing substantially non-converted resist, or alternatively developing the layer to remove the non-converted resist without removing substantially fully converted photoresist; and
I) performing a second etch of the second layer of etchable material in areas where the photoresist had been removed.

There may be two etchable layers (M1 and M2), or even three or more etchable layers (e.g., M1, M2, and M3), disposed on the insulating substrate and beneath the photoresist. The etchable layers are in the form of thin film, where each thin film can independently be semiconducting, insulating, or conducting materials. In the most immediate application, the two conducting films are conducting films, i.e., metal or doped silica, for example.

Advantageously the photoresist exposes acidic groups when converted by actinic energy, thereby becoming soluble in alkaline removers. Advantageously the photoresist is a conventional novalak/diazoquinone photoresist, or other combinations of compounds known in the art to react in a manner similar to a conventional novalak/diazoquinone photoresist. Advantageously, but not necessarily, the amine cross-linking agent comprises one or more of amino, diamine, or triamine compounds. Advantageously, but not necessarily, the amine cross-linking agent is a known cross-linking agent, for example a compound such as monazoline™. Using known compounds allows the process to be optimized with little experimentation. In such a case, the exposure to the first converting actinic energy makes the converted photoresist developable (removable) using an alkaline developer, for example an aqueous TMAH solution. The exposure to the second actinic energy causes the photoresist to expose acidic moieties, typically —COOH moieties, and the subsequent hard baking to activate and cure the exposed photoresist with the amine-based cross-linking agent prior to the second developing step will form a resist material that is tough and resistant to the acidic etchant used to etch the first and second etchable layers. The heated photoresist in areas not exposed to the second converting actinic energy are more soluble in selected solvents than the resist that had been exposed to actinic energy, because, since the photoresist had not been exposed to actinic energy to free up acidic carboxylic acid groups, there is no acidic material for the heat-activated cross-linking agent to react with in the areas not exposed to the second actinic energy. After etching the exposed areas of the first and second etchable layers, the areas not exposed to the second converting actinic energy can be removed by solvent, leaving a negative pattern (the area exposed to the second actinic energy) that is very acid resistant. Therefore, the etching of the first and second etchable layers in the first etching step, and the etching of the second etchable layer in the second etching step, will not adversely affect the converted and cross-linked resist. If dual exposure is used in the current invention, then the layer of photoresist deposited over the substrate can be of conventional thickness, whereas the method of U.S. Pat. No. 6,887,742 requires a thick (>1.9 microns) layer of photoresist. Finally, advantageously, after the second etch is performed, the remaining photoresist can be removed by dry etching or ashing such as is described in U.S. Pat. No. 6,887,742, or more preferably with a wet remover such as an aqueous hydroxylamine-alkanolamine-based remover. Advantageously, the first and second exposures can take place through first and second (different) masks, thereby eliminating the need for slit-screen masks.

A variant of the above process can be used with the slit-screen methodology in a process to manufacture TFT arrays such as liquid crystal panels described in U.S. Pat. No. 6,887,742, where the first and second exposures can both be through the same slit-screen mask. As described therein, after the substrate is provided in step A, and the layer of photoresist is deposited in step B, then step C would read: C) differentially exposing an area of the layer of photoresist to first converting actinic energy, such that there is at least one portion of the area that is substantially fully converted, at least one portion of the area that is partially converted, and at least one portion of the area that is substantially not converted. Then, the layer is developed to remove the substantially fully converted material. A portion of the thickness of the layer of partially converted photoresist would also be removed. The substrate would then be subjected to a second exposure through the same mask, and subsequent hard-baking at a temperature and for a time sufficient to activate and cure the amine-based cross-linking agent. Again, solvent can be used to remove the non-converted photoresist, leaving a pattern comprising the converted and cross-linked photoresist which, though it may be thinner than the original layer, is tough and acid resistant. This process has a number of other advantages over the slit screen process described in U.S. Pat. No. 6,887,742. For example, the fact that exposure to 50% of the necessary actinic energy in the process of U.S. Pat. No. 6,887,742 results is a top layer of the photoresist that is removable by alkaline (but not as removable as fully converted photoresist, leaving a bottom portion of the photoresist of lesser thickness which has been somewhat converted and can not stand up to strong etchants used in subsequent etching steps. In contrast, by using the photoresist with the amine cross-linking agent and the hard-bake step, the presence of partially converted photoresist in the bottom thickness of the resist layer (in areas exposed to partial converting energy) will simply reduce the time needed for the second exposure. Generally, it is highly advantageous that a second exposure be through a mask. In one embodiment, the second exposure is of very limited duration and is projected generally onto the remaining photoresist without pattern differentiation, where the small amount of actinic energy causes substantial increases in the conversion of the thinned layer of photoresist that is already partially converted by passage of a portion of the second actinic energy there-through, while such short exposure does not convert a sufficient amount of material in the thicker layer of photoresist not previously exposed to any converting actinic energy to form a layer resistant to removal by solvent. In one embodiment, no second exposure is performed, and the subsequent hard bake will cause the cross-linking agent to react with any converted photoresist that is in the bottom thickness of the photoresist layer that was partially removed during the first developing step. This is not preferred, however, because the toughness (if not the acid resistance) of the remaining layer of (partially) converted and cross-linked resist.

In one embodiment of the current invention, a first conducting layer M1 and a second conducting layer M2 are deposited on an insulating substrate, and then patterned to form a gate wire including a gate line and a gate electrode connected to the gate line. A gate insulating layer is formed which substantially covers the gate wire, and a semiconductor layer is formed on the gate insulating layer, typically but not always in a position disposed opposite to the gate electrode, are sequentially formed. A data wire including a data line intersecting the gate line, a source electrode connected to the data line and typically neighboring the gate electrode, and a drain electrode separated from the source electrode and opposite to the source electrode with respect to the gate electrode are then formed. Next, a passivation layer covering the data wire is formed, and a pixel electrode connected to the drain electrode is formed. During at least one of these processes, two patterns are formed from a single layer of deposited photoresist having heat-activated cross-linking agents therein, by either:
1) using a process of a) exposing pre-selected areas of the photoresist layer to first converting actinic energy, b) developing the photoresist to remove converted photoresist, thereby forming a first pattern, then c) exposing the photoresist to second converting activating energy, d) heating the photoresist to a temperature and for a time necessary to activate and advantageously cure the cross-linking agent, followed by e) etching the exposed conductive layers M1 and M2 to form the first pattern of circuitry, f) removing the non-converted photoresist with for example solvent removers that have differential removing capacity between the converted and cured resist versus non-converted and cured resist, thereby forming a second pattern, g) etching the second conducting layer M2 to form the second pattern of circuitry, and h) removing the remaining photoresist by ashing, dry etching, or preferably by liquid removers comprising an amine and/or an alkanolamine, hydroxylamine, optionally a polar organic solvent, and water; or
2) using a process of a) exposing pre-selected areas of the photoresist layer to first converting actinic energy and second converting actinic energy, such that areas exposed to first actinic energy are fully converted, while areas exposed to second actinic energy are only partially converted, b) developing the photoresist to remove converted photoresist, thereby forming a first pattern, then c) optionally exposing the photoresist to additional converting activating energy in an amount sufficient to more fully convert areas previously exposed to the second activating energy, but not in an amount sufficient to substantially convert photoresist in areas not exposed the first or second converting actinic energy, d) heating the photoresist to a temperature and for a time necessary to activate and advantageously cure the cross-linking agent, followed by e) etching the exposed conductive layers M1 and M2 to form the first pattern of circuitry, f) removing the non-converted photoresist with for example solvent removers that have differential removing capacity between the converted and cured resist versus non-converted and cured resist, thereby forming a second pattern, g) etching the second conducting layer M2 to form the second pattern of circuitry, and h) removing the remaining photoresist by ashing, dry etching, or preferably by liquid removers comprising an amine and/or an alkanolamine, hydroxylamine, optionally a polar organic solvent, and water. In the second alternative, the gate wire may be formed through one photolithography step using a photoresist pattern having different thickness depending on positions. The photoresist pattern may have a first portion having a first thickness, a second portion having a second thickness larger than the first portion, and a third portion having a third thickness smaller than the first thickness. In the first alternative discussed above, the photoresist layers will be substantially unchanged in thickness during the process, until the photoresist is removed.

This invention will reduce the number of lithography steps in LCD TFT manufacturing. The invention is to formulate a photoresist composition using conventional novalak/diazoquinone photoresist with an amine cross-linking agent, such as commercially available compound diamine, triamine, etc. This invention can utilize the “slit masks” which transmit differential amounts of actinic energy to areas of the substrate, or it can utilize conventional masks but still reduces the number of steps in the manufacturing process because the layer of photoresist deposited for the first etching step can be re-used in the second etching step. The method to use these resist formulations is explained in the attached drawings. The resist is exposed using Mask 1 and the pattern is developed using alkaline developer, such as 2.38% TMAH solution (Step 1 and 2). After the first pattern is transferred to the photoresist, a second exposure using Mask 2 is made. During the exposure, the photoactive compound—diazoquinone—is converted to carboxylic acid compound. The substrate with patterned photoresist is then cured at temperatures sufficient to activate and cure the cross-linking agent, and preferably at a temperature from 150° C.-200° C. At this elevated temperature, the amine cross-linking agent reacts with the Novolak and the carboxylic moiety in the photoactive compound. As a result of this curing, the exposed area becomes more difficult to solubilize in a select group of solvents than the non-exposed area. In addition, due to higher baking temperature, the resist is more resistant to etching solution (step 3 and 4)

The first etching step is carried out after the substrate has been hard baked. Thereby the mask 1 pattern is transferred to the thin film metal substrate (step 5). In developing the second image, a solvent developer is used instead of alkaline developer. A selected solvent will dissolve the non-exposed area. This causes the photoresist behaving like a negative tone resist (step 6). After the mask 2 pattern has been transferred to the photoresist, mask 2 is selectively etched away while mask 1 remains on the substrate (step 7). After the resist pattern is transferred to mask 2, the remaining photoresist is removed using photoresist stripper and results in final metal film structures on the substrate.

### BRIEF DESCRIPTION OF THE DRAWINGS

FIG. 1 is a layout view of a thin film transistor array panel for a liquid crystal display.

FIG. 2 is cross-sectional view showing details of major structures in a TFT.

FIGS. 3a to 3f shows a detailed cross-sectional view of major components of a TFT as they exist at the end of certain manufacturing processes.

FIGS. 4a to 4f show the process used in U.S. Pat. No. 6,887,742 which includes a step where two patterns are formed through one photolithography process.

FIGS. 5a to 5f show the process used in the current invention on the right, and the process used in U.S. Pat. No. 6,887,742 on the left, for ready comparison.

FIGS. 6a to 6e show another process used in the current invention.

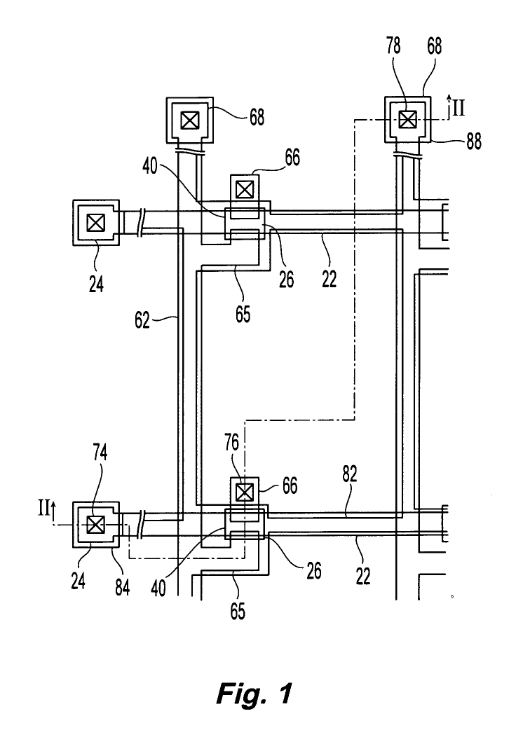

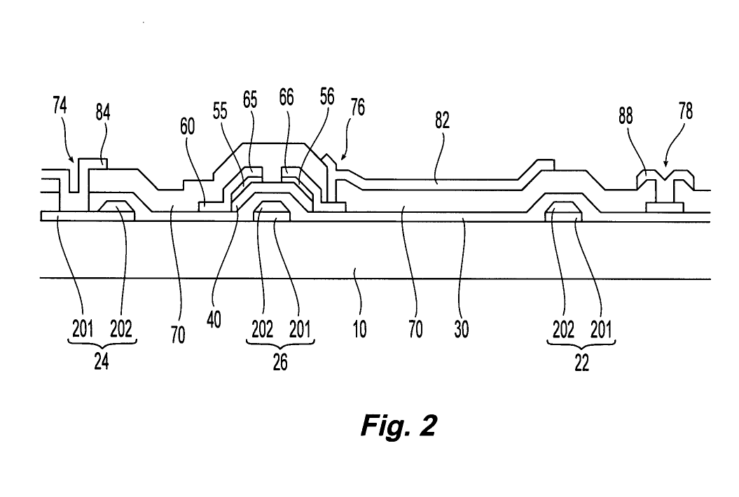

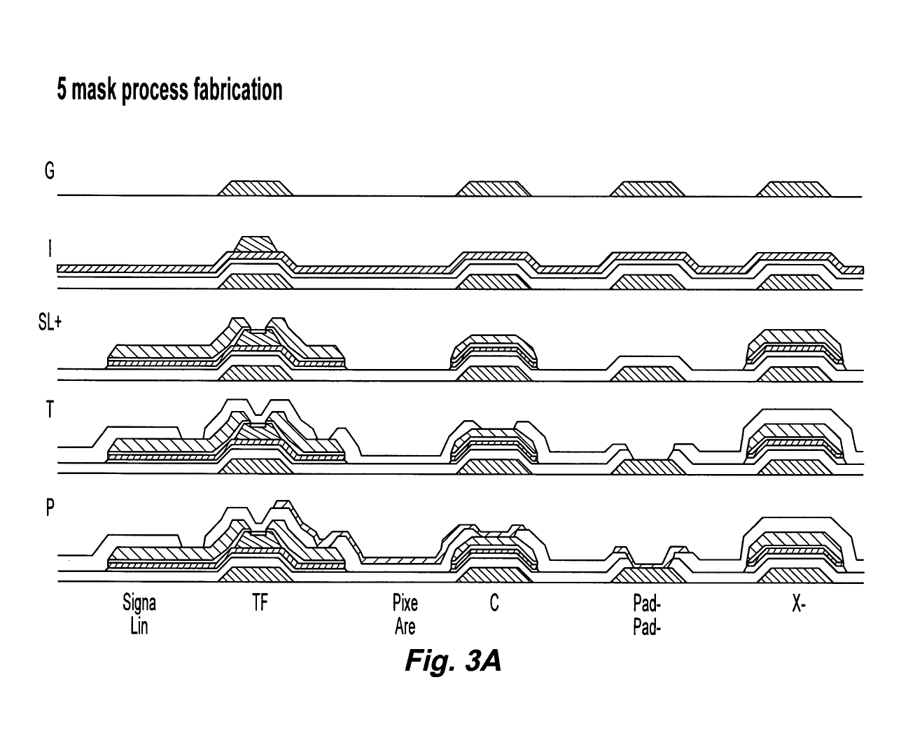

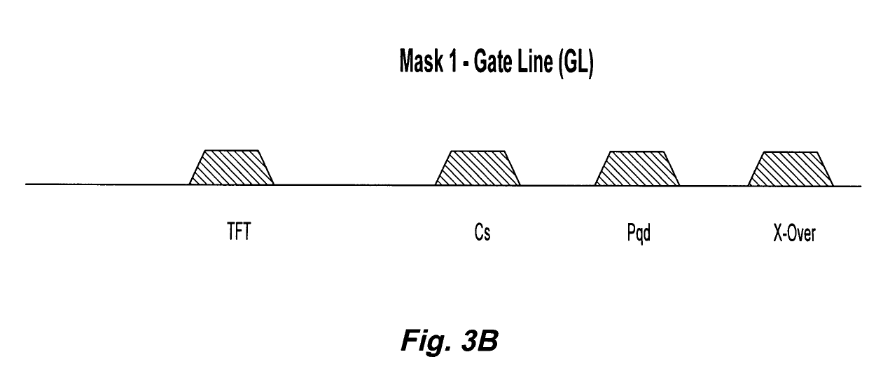

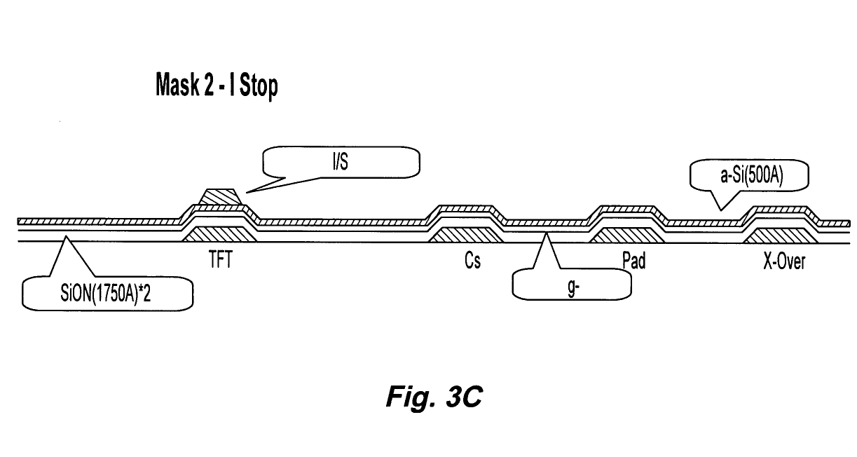

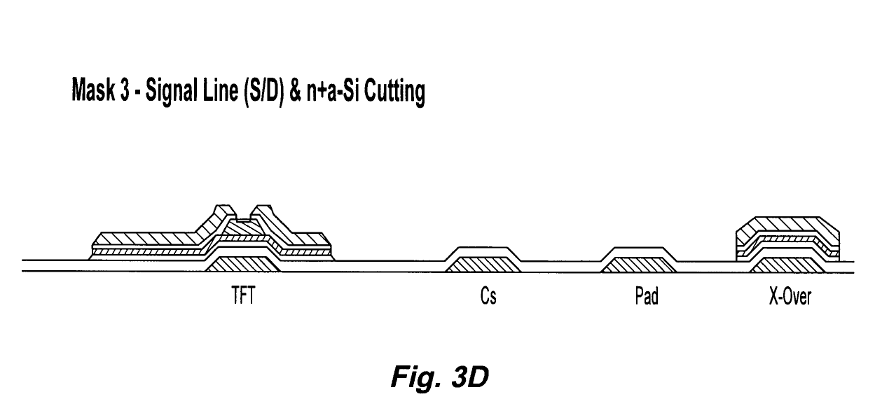

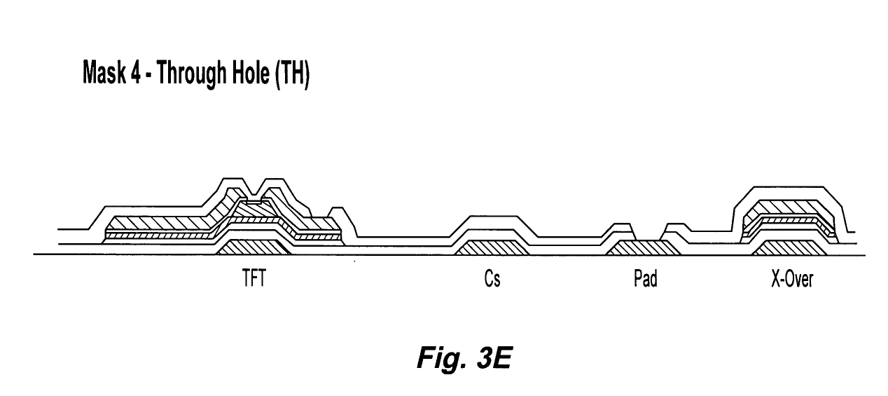

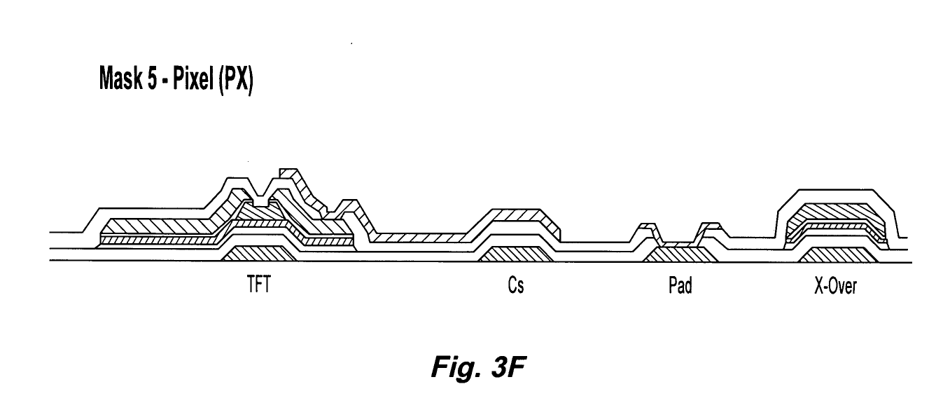

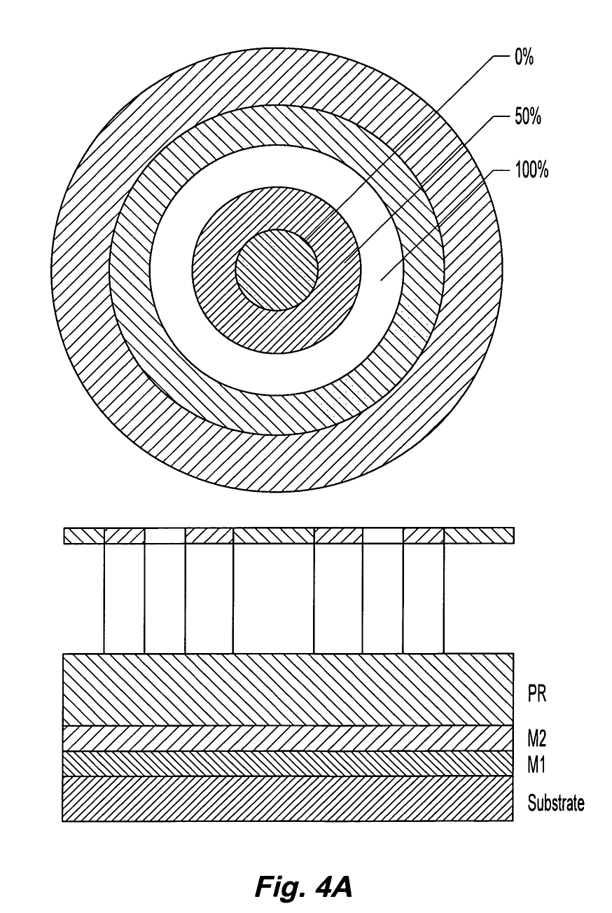

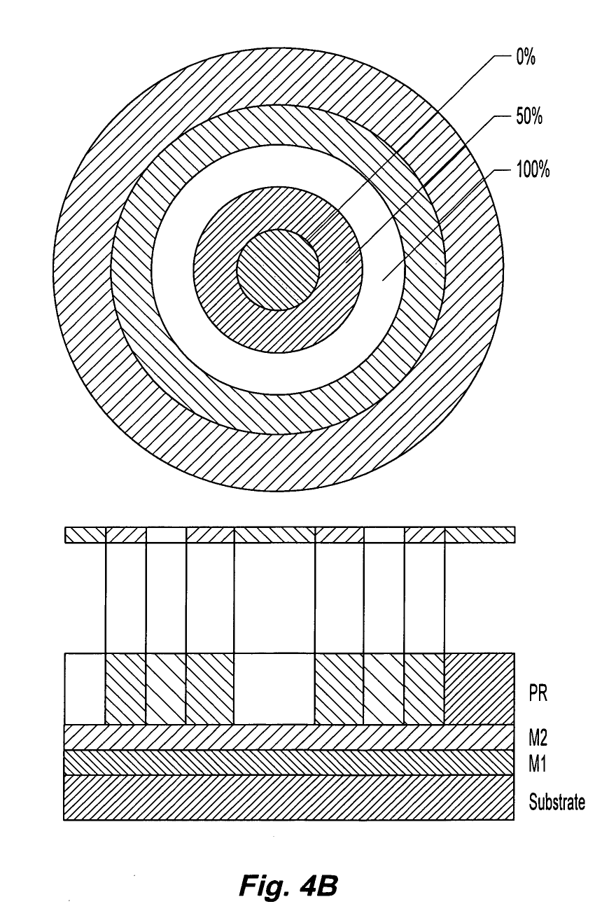

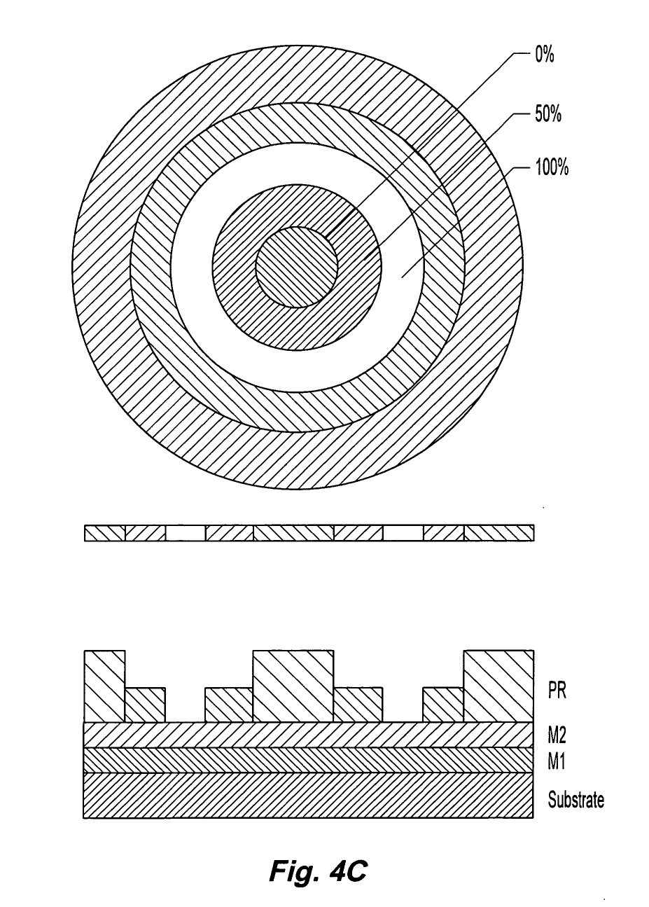

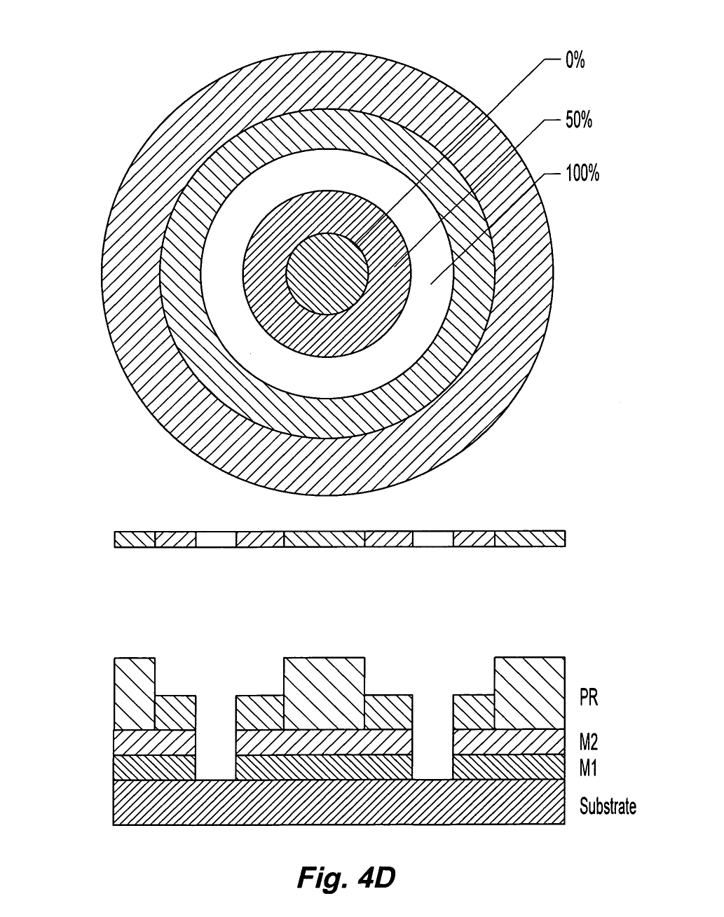

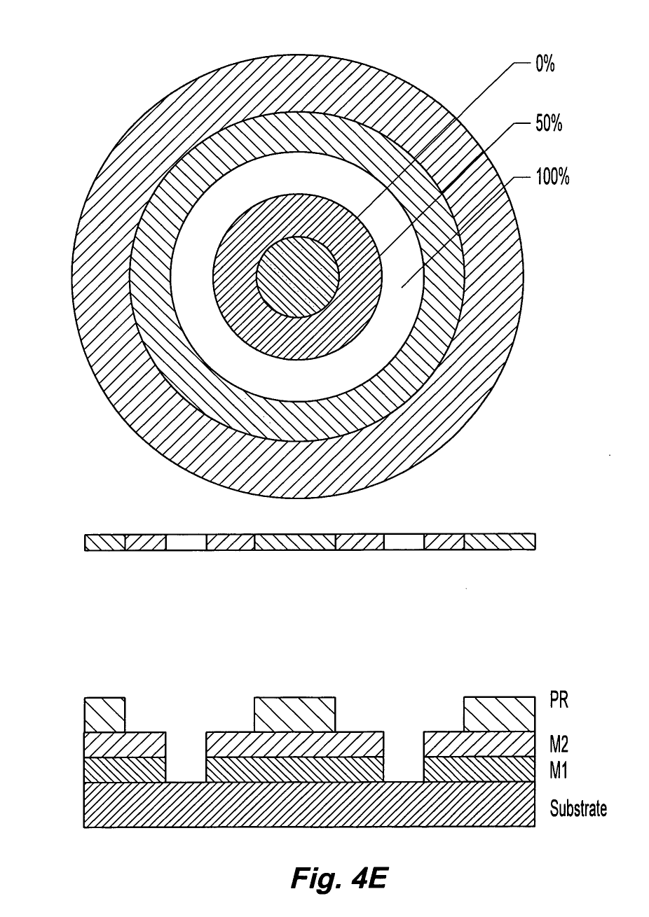

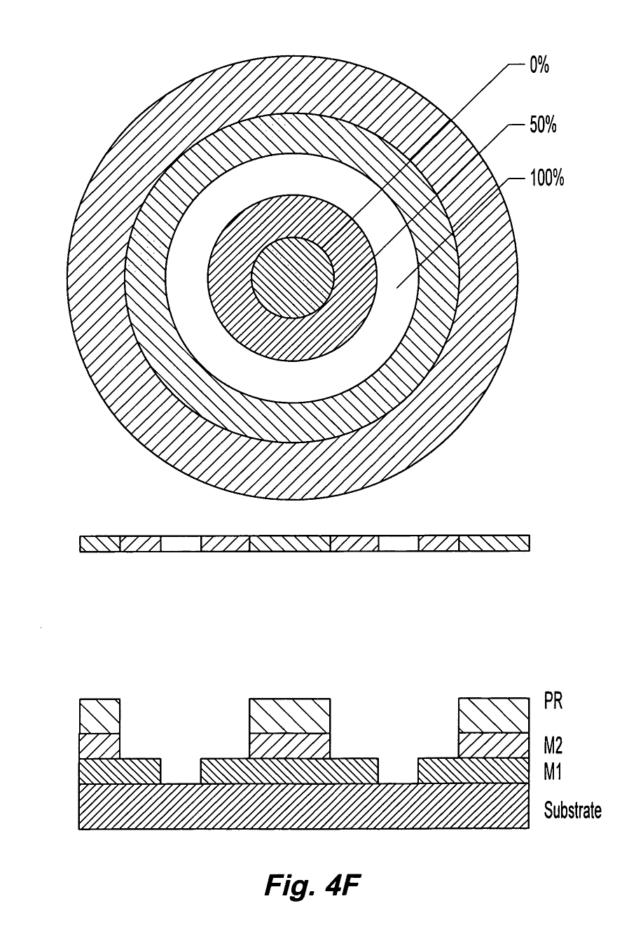

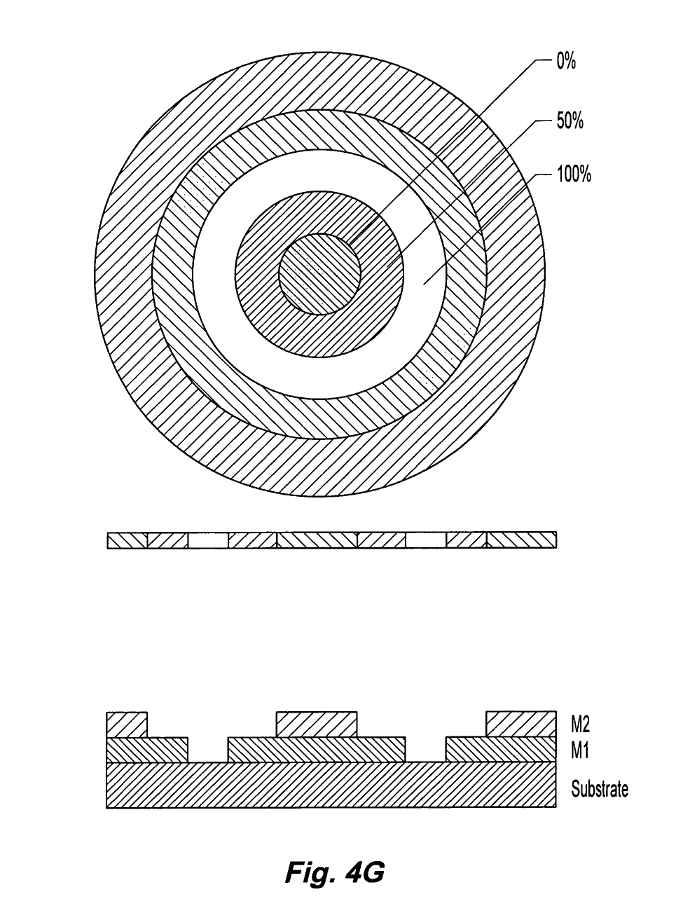

### DETAILED DESCRIPTION OF EMBODIMENTS

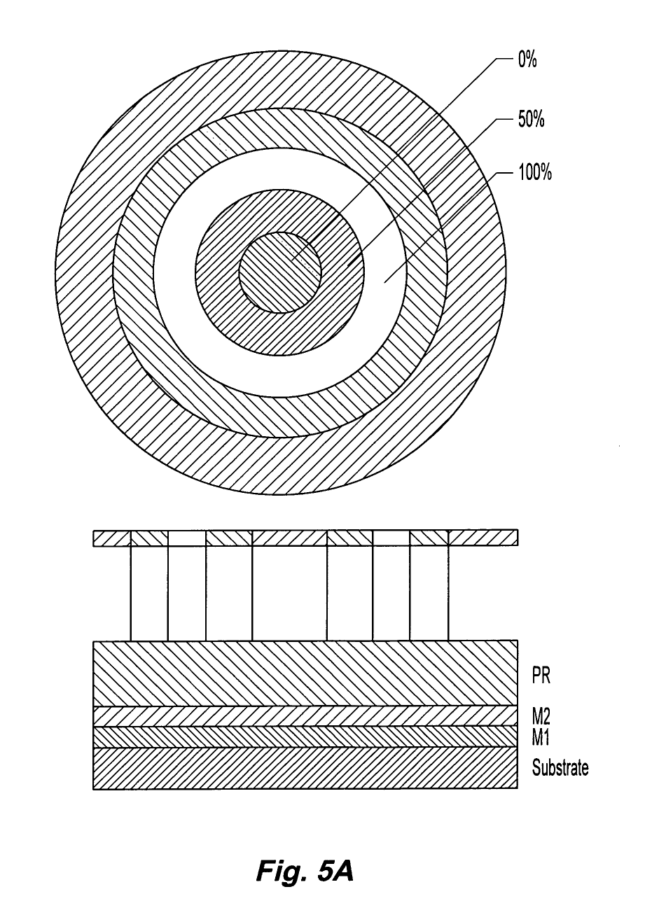

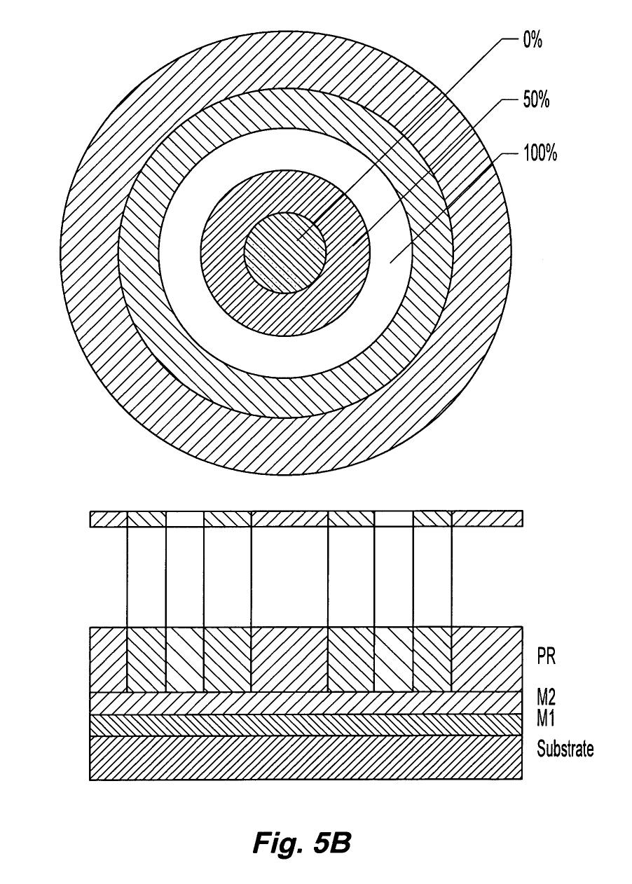

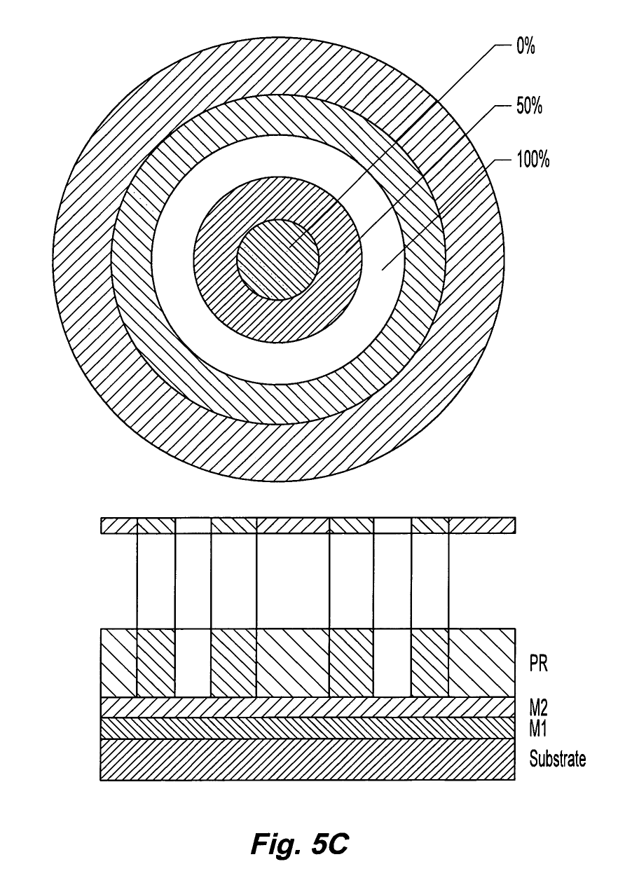

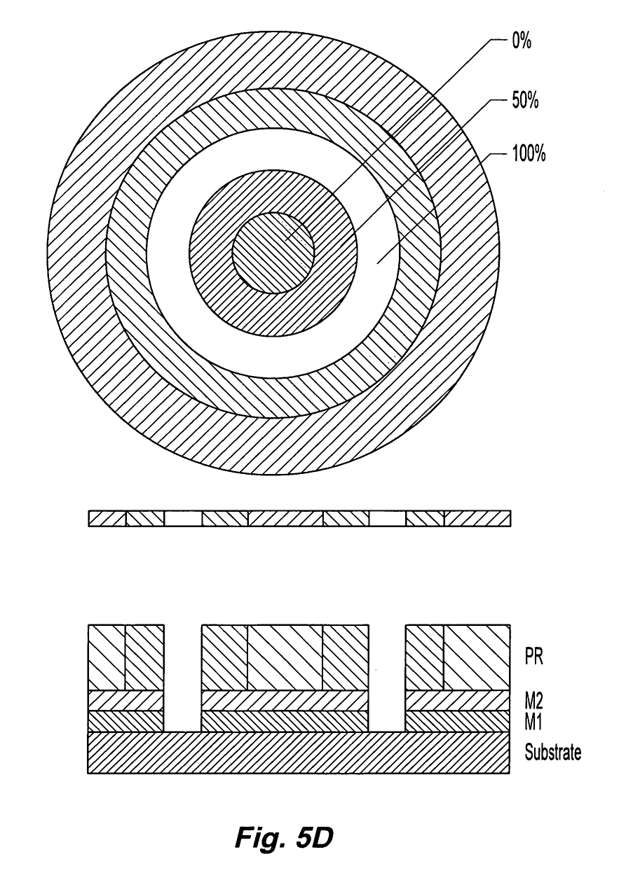

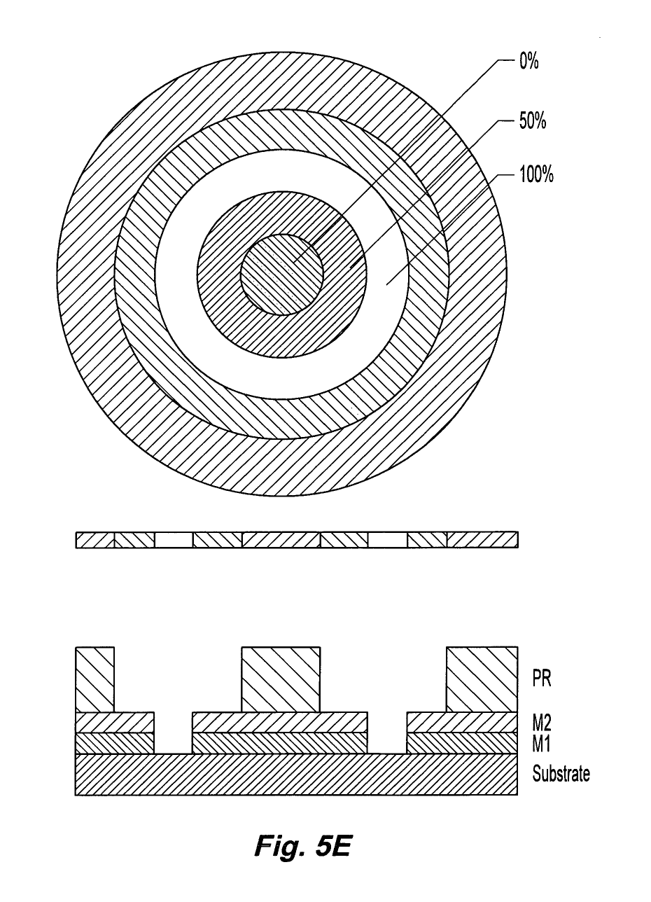

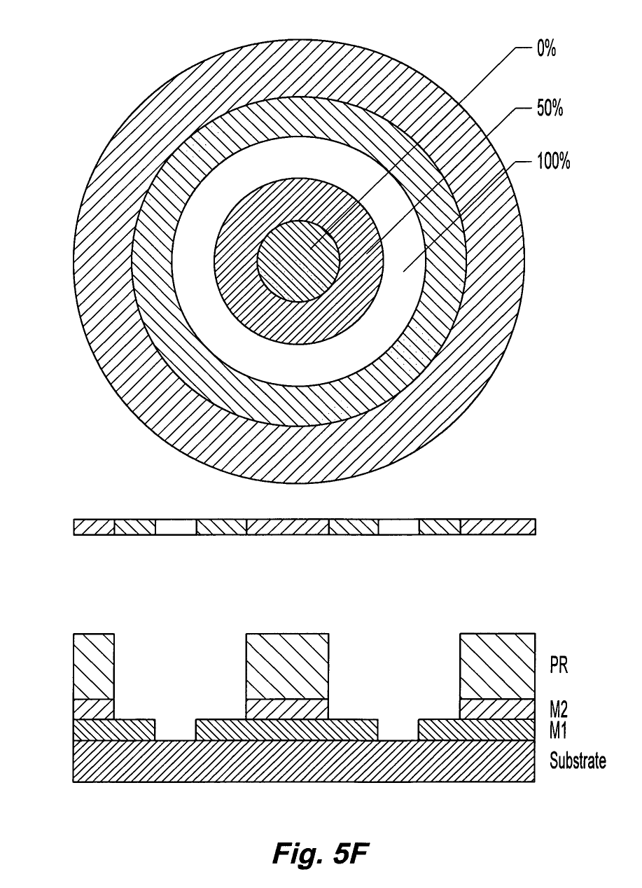

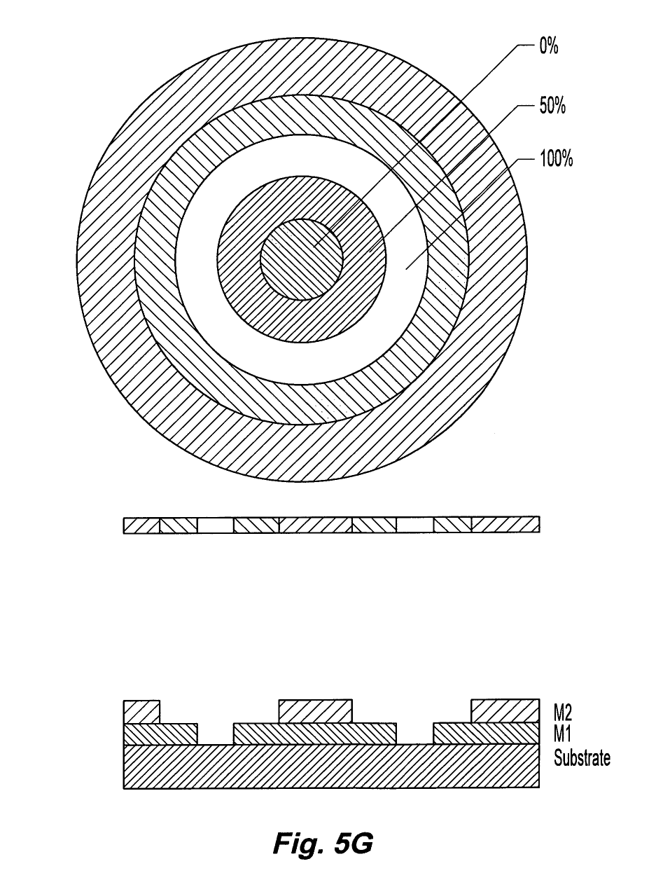

It is advantageous to compare the methodology described in U.S. Pat. No. 6,887,742 with the methodology of a preferred embodiment of the current invention. FIGS. 5a to 5f show the process used in the current invention on the right, and the process used in U.S. Pat. No. 6,887,742 on the left, for ready comparison, where the end TFT product of the processes a the same.

The method of U.S. Pat. No. 6,887,742 utilizes a conventional photoresist, e.g., that becomes soluble in a remover after exposure to a converting amount of actinic energy. It is well known in the art to produce positive photoresist formulations such as those described in U.S. Pat. Nos. 3,666,473; 4,115,128; and 4,173,470. These include alkali-soluble phenol-formaldehyde Novolak resins together with light-sensitive materials, usually a substituted naphthoquinone diazide compound. The resins and sensitizers are dissolved in an organic solvent or mixture of solvents and are applied as a thin film or coating to a substrate suitable for the particular application desired. The resin component of these photoresist formulations is soluble in aqueous alkaline solutions, but the sensitizer is not. Upon imagewise exposure of the coated substrate to actinic radiation, the exposed areas of the coating are rendered more soluble than the unexposed areas. This difference in solubility rates causes the exposed areas of the photoresist coating to be dissolved when the substrate is immersed in an alkaline developing solution while the unexposed areas are largely unaffected, thus producing a positive relief pattern on the substrate. Similarly, the process of the present invention utilizes a conventional photoresist, e.g., a novalak/diazoquinone photoresist with an amine cross-linking agent, such as commercially available compound diamine, triamine, etc., that becomes soluble in alkaline remover on exposure to a converting amount of actinic energy. Alkali soluble resins useful in this invention include phenol-formaldehyde resins, cresol-formaldehyde resins, styrene-maleic anhydride copolymers, alkyl vinyl ether-maleic anhydride copolymers, and the like. The o-quinone diazide compounds include o-benzoquinone diazides, o-naphthoquinone diazides and o-anthraquinone diazides. Such materials are sensitive to light in the wavelength range of from about 290 to 500 nm. When used in the standard manner, photo-exposure causes the alkali insoluble o-quinone diazide of the positive plate to be converted into an alkali soluble carboxylic acid. Upon subsequent treatment with a developer, which is a dilute aqueous alkaline solution, the exposed parts of the coating are removed. The unexposed coating is alkali insoluble, because the o-quinone diazide is unaffected by the developer, and remains on the substrate.

However, the photoresist composition of a preferred embodiment of the current invention further comprises heat-activated and cured cross-linkers, preferably amine-type cross-linkers that can react with exposed carboxylic acid groups in the converted photoresist. U.S. Pat. No. 4,104,070 describes the use of imidazolines; U.S. Pat. No. 4,196,003 describes the use of a variety of secondary and tertiary amines and U.S. Pat. No. 4,356,254 describes the addition of basic carbonium dyes. The disclosures of these afore-mentioned patents are incorporated herein by reference thereto. Because the photoresist contains this cross-linking agent in an amount sufficient to react with the remaining resist to form a cross-linked resist upon exposure to converting actinic energy followed by exposure to curing temperature, a suitable slit-screen mask for use with the current invention is different than the mask used in U.S. Pat. No. 6,887,742. As shown in FIG. 5a, the areas requiring full transmittance of light are the same for the process described in U.S. Pat. No. 6,887,742 and for the process of the current invention. However, in areas where secondary patterning is desired, U.S. Pat. No. 6,887,742 used 50% transmittance mask material, while the current invention uses 0% transmittance mask material. In areas where the mask is intended to remain until both etching steps are concluded, U.S. Pat. No. 6,887,742 used 0% transmittance mask material, while the current invention uses 50% transmittance mask material. The reason for this will become clear in subsequent steps.

FIG. 5b shows the results of the exposure to actinic energy through the mask. For the U.S. Pat. No. 6,887,742 method depicted on the left, fully converted photoresist is shown as intermediate gray color, non-converted photoresist is shown as light gray, and partially converted photoresist is shown as black. In contrast, for the current invention, fully converted photoresist is shown as intermediate gray color, non-converted photoresist is shown as black, and partially converted photoresist is shown as light gray. In the first developing step depicted in FIG. 5c, all of the fully exposed photoresist is removed, by example with aqueous TMAH or other alkaline cleaner. The method of U.S. Pat. No. 6,887,742 does not describe the developer used, but it is likely a conventional alkaline remover that removes converted photoresist that becomes soluble in a remover after exposure to a converting amount of actinic energy. The presence of the amine in the photoresist of the current invention may make reduce the amount of partially converted photoresist removed during this first developing stage, but the drawings showing no removal of partially converted photoresist are in error. FIG. 5c mentions that the substrate is developed, and then undergoes a hard bake at for example 150° to 200° C.

The substrate is then exposed to the first etchant used to etch away exposed layers M2 and the M1. Such etchant is typically a strong acid or other reactive material. In the process described in U.S. Pat. No. 6,887,742, the acidic first etchant eats away at and causes contraction of the remaining resist (both the converted and partially converted layers). In the current invention, the cross-linking agent may impart some resistance against acid to the non-converted but cured photoresist, but will impart even more resistance to acid to the converted and cured photoresist. The resist is substantially more resistant to attack from the etchant, and the pattern resolution is not compromised. FIG. 5e shows the results of the second developing step. In U.S. Pat. No. 6,887,742, they use a universal remover to try to remove a certain thickness, such that all of the areas previously having partially converted photoresist which were thinned in the first developing step are free of resist, while the areas not exposed to converting actinic energy still have sufficient thickness to act as a resist. In addition to the pattern resolution problems, it can be appreciated that the development step in the method described in U.S. Pat. No. 6,887,742 is prone to failure unless the exposure time and conditions to the photoresist remover are stringently controlled. In contrast, in the process of the current invention, non-converted photoresist is removed by a solvent, while the converted and thermally cured resist is substantially impervious to the solvent. Control of the second resist development step in the current invention does not need the stringent controls necessary for the process described in U.S. Pat. No. 6,887,742. FIG. 5f shows the etching of the M2 layer, and FIG. 5g shows the final step of removing the resist. U.S. Pat. No. 6,887,742 suggests ashing to remove the resist, and while that is possible for the instant invention, removal with a wet resist remover is preferable, to prevent subsequent problems associated with etch residue.

In the current invention, the first development step uses an alkaline remover such as aqueous TMAH, the second developing step uses a solvent-based remover, and the final removal step advantageously uses an aqueous photoresist stripper.

Advantageously, even in a process such as described in U.S. Pat. No. 6,887,742 and in published application 2005/0139836, where no cross-linking agent is disclosed, a hard bake after the first developing step is expected to improve the resistance of the remaining photoresist to the acidic etchants, but the presence of the cross-linker makes the protection much more effective.

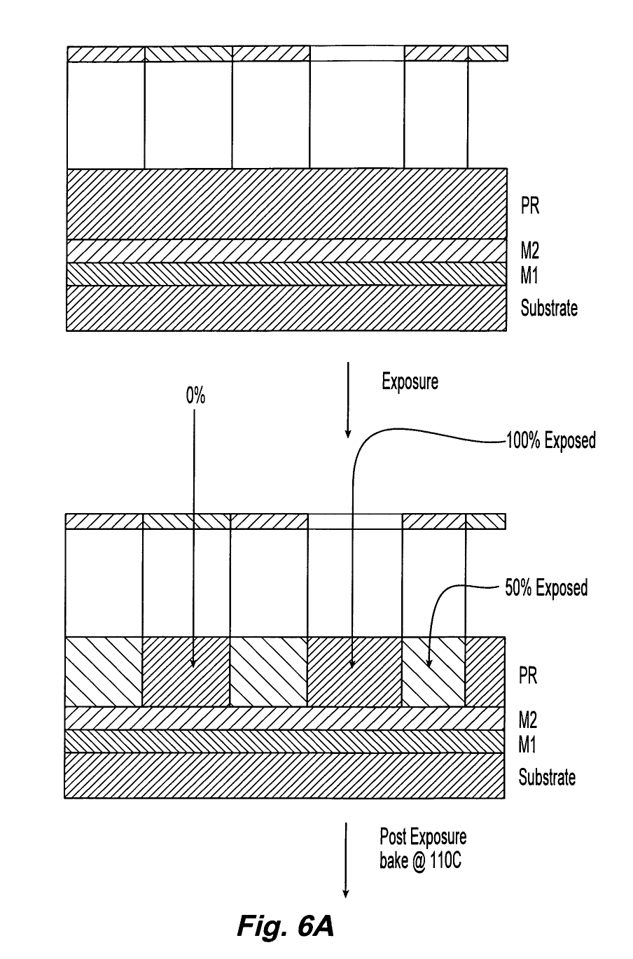

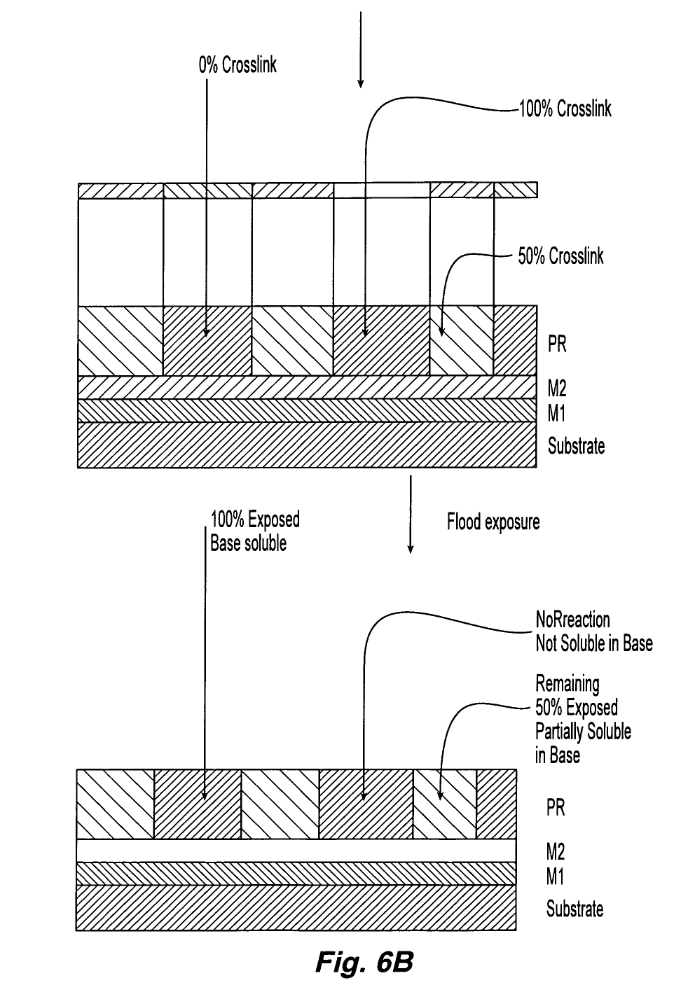

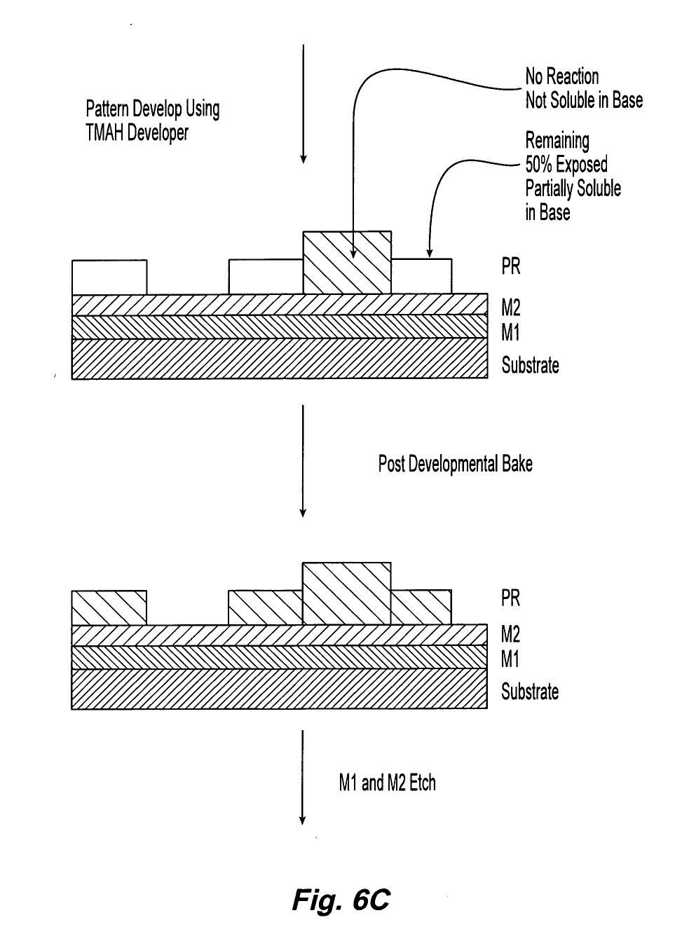

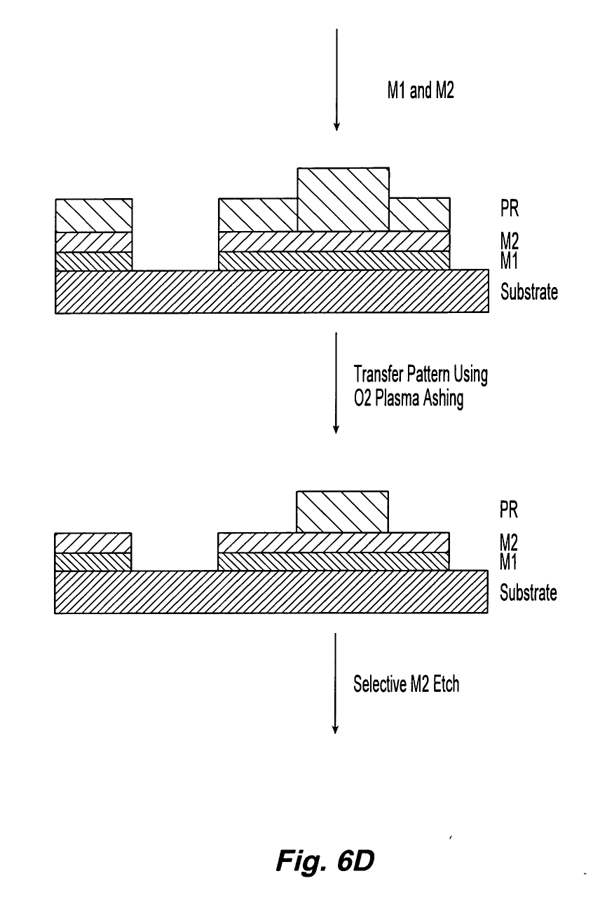

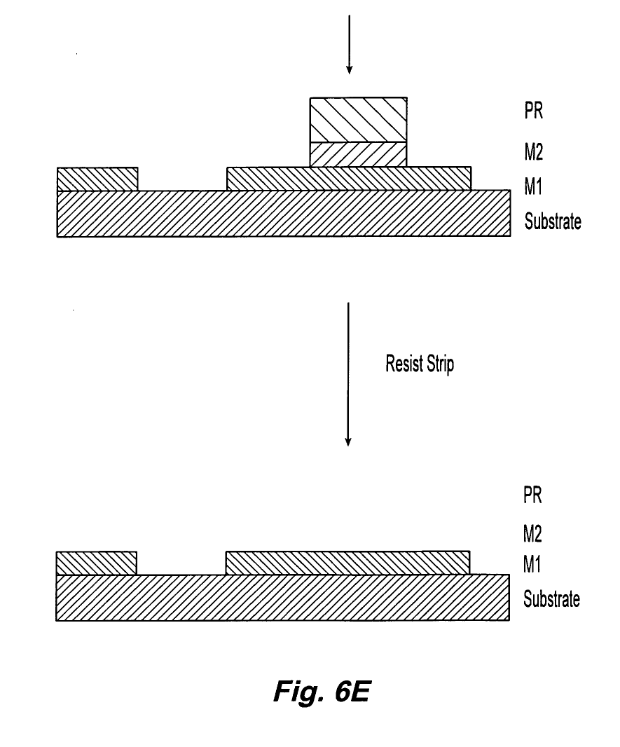

It may be observed that the formation of the negative resist in the present process is similar to the conventional formation of negative resists. An early disclosure of a method for making a negative resist is U.S. Pat. No. 4,104,070, the disclosure of which is incorporated here for all legal purposes. U.S. Pat. No. 4,104,070 describes a method of making a negative photoresist image on a substrate, where a normally positive working photoresist material containing 1-hydroxyethyl-2-alkyl-imidazoline is applied to a substrate, image-wise exposed with actinic radiation, heated, and blanket exposed to actinic radiation. The material which was not exposed originally is then removed with a solvent to give a negative image. FIGS. 6a to 6e provide another embodiment of the invention to manufacture a TFT array, and in particular a liquid crystal display. In some manufacturing processes, there are materials that are sensitive to elevated temperatures, and the lower curing temperatures described in U.S. Pat. No. 4,104,070 can be advantageous.

According to their interaction with light, a distinction is made between negative and positive photoresist systems. The term negative refers to a photoresist which after exposure in a suitable solvent is insoluble, whereas the unexposed resist zones are dissolved by the developer. As a result, free and unprotected zones are obtained on the substrate surface which correspond to the opaque dark parts of the photomask. In a positive working photoresist system, the photoresist system is altered upon exposure in such a manner that it is subsequently soluble in the developer (e.g., aqueous buffered alkali). The exposed areas of the photoresist film are removed upon developing, and the free unprotected areas on the substrate surface correspond to the transparent parts on the photomask. Examples of positive working photoresist systems are photoresist materials based on phenol-formaldehyde resins (Novolak type) with a suitable molecular weight distribution, which contain a photoactive compound, a so-called sensitizer, for instance of the group of the 4 or 5-substituted diazo-naphthoquinones, such as naphthoquinone (1,2)-diazide-sulfonic acid esters. Such photoresists are useful in the present invention, when combined with an amine cross-linking agent such as 1-hydroxyethyl-2-alkylimidazoline present in an amount between, for example, 0.2% to 5% by weight of the photoresist. The various cross-linking agents differ greatly in functionality and in molecular weight, so it is impractical to specify a general preferred amount of cross-linking agent to include in the resist. One skilled in the art will have ready access to preferred amounts when a particular cross-linking agent is selected. To activate the cross-linking agent, U.S. Pat. No. 4,104,070 suggests heating to a temperature of 105° to 110° C. for 10 to 20 minutes. As is known in the art, the heating time can be under a minute is a hot plate is used as opposed to an oven, and shorter times can be used if higher temperatures are employed.

FIG. 6a shows the use of the slit-mask to provide zero intensity, a first intensity, and a second intensity light to different areas of the photoresist disposed on the substrate having a first conductive layer M1 on the substrate and a second conductive layer M2 disposed over M1. As described previously, the result is areas of the substrate having photoresist that is partially converted, areas of the substrate having photoresist that is fully converted, and areas of the substrate having photoresist that is non-converted. After this first exposure, unlike previous processes, the substrate and photoresist undergo a hard bake, for example at between 105° C. to 110° C. As shown in FIG. 6b, the result of the hard bake is areas of the substrate having photoresist that is partially converted and partially cross-linked, areas of the substrate having photoresist that is fully converted and fully cross-linked, and areas of the substrate having photoresist that is non-converted and not cross-linked. There follows a 100% indiscriminate exposure to converting actinic energy, followed by development with an alkaline remover such as aqueous TMAH to remove photoresist from areas of the substrate having photoresist that is non-converted and not cross-linked, as is shown in FIGS. 6b and 6c. In this embodiment, the alkaline remover will again remove a portion of the partially exposed and partially cross-linked resist. Following this development, there is advantageously a post-development hard bake, as shown in FIG. 6c, followed by etching of layers M2 and M1, to give the substrate shown at the top of FIG. 6d. In a method similar to that described in U.S. Pat. No. 6,887,742, for example, there follows a second development using O₂ plasma etching to remove a thickness of resist. By carefully controlling the time and conditions of this etch, areas having partially converted and partially cross-linked resist will become free of resist, while the areas having a full thickness of tough fully converted and fully cross-linked resist will have a significant and useful amount of resist remaining. Thereafter, as is shown in FIGS. 6d and 6e, a selective etch of layer M2 followed by stripping off the resist, advantageously with a resist remover, the final product is formed.

In an alternate embodiment, the invention is a photolithography process for fabricating a thin film transistor comprising: A) providing a substrate comprising an insulating layer, a first layer of first etchable material disposed over the insulating layer, and a second layer of second etchable material, different from the first etchable material, disposed over the first layer of etchable material; B) depositing a layer of Novolak-type resist having photosensitizers and having an amine cross-linking agent that is activated by holding the resist at an elevated curing temperature for a predetermined amount of time on said second layer of etchable material; C) differentially exposing an area of the layer of photoresist to first converting actinic energy, such that there is at least one portion of the area that comprises substantially fully converted photoresist, and at least one portion of the area that comprises substantially non-converted photoresist; D) in a first developing step developing the layer to remove the substantially fully converted photoresist without removing substantially non-converted resist, using for example an alkaline remover; E) differentially exposing an area of the layer of photoresist to second converting actinic energy, such that there is at least one portion of the area that comprises converted photoresist, and at least one portion of the area that comprises non-converted photoresist; F) curing the photoresist at a temperature sufficient to activate the amine cross-linking agent, for example at a temperature between 110° C. to 250° C., typically between 130° C. to 220° C., and preferably (depending on the cross-liking agent selected) between about 150° C. to 200° C.; G) performing a first etch of the first and second layers of etchable material disposed in areas where the photoresist had been removed; H) Fully exposing the remaining photoresist to converting actinic energy, and developing (removing) the remaining photoresist that had not been thermally cured in a second developing step, using either an alkaline remover, a solvent remover, or a hybrid alkaline/solvent remover; and I) performing a second etch of the second layer of etchable material in areas where the photoresist had been removed.

The invention has been illustrated by the embodiments described above, but is not intended to be limited to those embodiments.

1. A method of forming a thin film transistor comprising:
A) providing a substrate comprising an insulating layer, a first layer of first etchable material disposed over the insulating layer, and a second layer of second etchable material, different from the first etchable material, disposed over the first layer of etchable material;
B) depositing a layer of photoresist on said second layer of etchable material, said layer having an area and a thickness, and said photoresist comprising polymers that are altered by actinic energy and also comprising an amine cross-linking agent that is activated by holding the resist at an elevated curing temperature for a predetermined amount of time;
C) differentially exposing an area of the layer of photoresist to first converting actinic energy, such that there is at least one portion of the area that comprises substantially fully converted photoresist, and at least one portion of the area that comprises substantially non-converted photoresist;
D) in a first developing step developing the layer to remove the substantially fully converted photoresist without removing substantially non-converted resist, or alternatively developing the layer to remove the non-converted resist without removing substantially fully converted photoresist;
E) differentially exposing an area of the layer of photoresist to second converting actinic energy, such that there is at least one portion of the area that comprises converted photoresist, and at least one portion of the area that comprises non-converted photoresist;
F) curing the photoresist at a temperature sufficient to activate the amine cross-linking agent, for example at a temperature between 110° C. to 250° C., typically between 130° C. to 220° C., and preferably (depending on the cross-liking agent selected) between about 150° C. to 200° C.;
G) performing a first etch of the first and second layers of etchable material disposed in areas where the photoresist had been removed;
H) developing the remaining photoresist that had been thermally cured in a second developing step to remove the substantially fully converted photoresist without removing substantially non-converted resist, or alternatively developing the layer to remove the non-converted resist without removing substantially fully converted photoresist; and
I) performing a second etch of the second layer of etchable material in areas where the photoresist had been removed.

2. The method of claim 1 wherein the photoresist composition becomes soluble in alkaline removers when converted by actinic energy.

3. The method of claim 1 wherein the photoresist is a conventional novalak/diazoquinone photoresist, and the amine cross-linking agent is a diamine or a triamine.

4. The method of claim 1 wherein exposure of the photoresist to converting actinic energy and the subsequent hard baking to activate and cure the exposed photoresist with the amine-based cross-linking agent forms a resist material that is tough and resistant to the acidic etchant used to etch the first and second etchable layers.

5. The method of claim 1 wherein, after the first etching step of etching the exposed areas of the first and second etchable layers, the areas not exposed to the second converting actinic energy are removed by contacting the layer of photoresist with solvent.

6. The method of claim 1 wherein the first and second exposures can take place through first and second different masks.

7. The method of claim 1 wherein the first and second exposures can both be through the same slit-screen mask.

8. A method of forming a liquid crystal display device comprising:
A) depositing a first conducting layer M1 and a second conducting layer M2 on an insulating substrate, said conducting layers comprising materials to form a gate wire including a gate line and a gate electrode connected to the gate line, respectively; B) depositing on the a photoresist having heat-activated cross-linking agents therein;
C) exposing pre-selected areas of the photoresist layer to first converting actinic energy,
D) developing the photoresist to remove converted photoresist, thereby forming a first pattern, then
E) exposing the photoresist to second converting activating energy,
F) heating the photoresist to a temperature and for a time necessary to activate and advantageously cure the cross-linking agent, followed by
G) etching the exposed conductive layers M1 and M2 to form the first pattern of circuitry,
H) removing the non-converted photoresist with for example solvent removers that have differential removing capacity between the converted and cured resist versus non-converted and cured resist, thereby forming a second pattern,
I) etching the second conducting layer M2 to form the second pattern of circuitry, and
J) removing the remaining photoresist by ashing, dry etching, or preferably by liquid removers comprising an amine and/or an alkanolamine, hydroxylamine, optionally a polar organic solvent, and water.

9. The method of claim 8 further comprising the steps of:
K) forming a gate insulating layer which substantially covers the gate wire;
L) forming a semiconductor layer on the gate insulating layer;
M) forming a data wire including a data line intersecting the gate line, a source electrode connected to the data line and, and a drain electrode separated from the source electrode;
N) forming a passivation layer covering the data wire, and
O) forming a pixel electrode connected to the drain electrode.

10. A method for fabricating a liquid crystal display device, comprising:
A) forming a pixel electrode on a substrate;
B) forming a first conductive layer on the pixel electrode;
C) depositing a layer of photoresist on the first conductive layer;
D) forming one or more photoresist patterns on the conductive layer, and etching as needed to form a source electrode forming portion, a channel forming portion and a pixel electrode forming portion using the patterned photoresist layer as a mask;
E) forming a semiconductor layer over a surface of the substrate;
F) forming an insulating layer on the semiconductor layer;
G) forming a second conductive layer on the insulating layer;
H) depositing a second layer of photoresist on the second conductive layer;
I) forming one or more photoresist patterns on the second conductive layer;
J) forming an active layer using a photoresist pattern; and
K) forming a gate electrode on the active layer,
wherein at least one layer of photoresist has two or more patterns formed thereon, wherein said photoresist layer having two or more patterns formed thereon are formed by:
1) supplying a photoresist comprising polymers that are altered by actinic energy and also comprising an amine-type cross-linking agent that is activated by holding the resist at an elevated temperature for a predetermined amount of time;
2) differentially exposing an area of the layer of photoresist to first converting actinic energy, such that there is at least one portion of the area that comprises substantially fully converted photoresist, and at least one portion of the area that comprises substantially non-converted photoresist;
3) in a first developing step developing the layer to remove the substantially fully converted photoresist without removing substantially non-converted resist, thereby forming a first pattern;
4) differentially exposing an area of the layer of photoresist to second converting actinic energy, such that there is at least one portion of the area that comprises converted photoresist, and at least one portion of the area that comprises non-converted photoresist;
5) curing the photoresist at a temperature sufficient to activate the amine-type cross-linking agent, for example at a temperature between 110° C. to 250° C., typically between 130° C. to 220° C., and preferably (depending on the cross-liking agent selected) between about 150° C. to 200° C.;
6) performing a first etch of the layers of etchable material disposed in areas where the photoresist had been removed;
7) developing the photoresist that had been thermally cured in a second developing step to form a second pattern; and
8) performing a second etch of a layer of etchable material in areas where the photoresist had been removed.

11. The method of claim 10, wherein the first converting actinic energy and the second converting actinic energy are supplied simultaneously by using a slit mask and by slit exposure.

12. The method of claim 10, wherein forming the source electrode forming portion, the channel forming portion and the pixel electrode forming portion using the first photoresist film patterned as a mask includes: developing the photoresist to form a first mask, removing the first conductive layer of the channel forming portion and the pixel electrode forming portion; developing the photoresist to form a second mask; and removing the first conductive layer on the pixel electrode.
